(19) United States
(12) Patent Application Publication
(10) Pub. No.: US 2015/0170916 A1
(43) Pub. Date: Jun. 18, 2015

(54) SEMICONDUCTOR PROCESS FOR MANUFACTURING EPITAXIAL STRUCTURES

(71) Applicant: UNITED MICROELECTRONICS CORP., Hsin-Chu City (TW)

(72) Inventors: Tien-Wei Yu, Kaohsiung City (TW); Chun-Jen Chen, Tainan City (TW); Tsung-Mu Yang, Tainan City (TW); Ming-Hua Chang, Tainan City (TW); Yu-Shu Lin, Pingtung County (TW); Chin-Cheng Chien, Tainan City (TW)

(73) Assignee: UNITED MICROELECTRONICS CORP., Hsin-Chu City (TW)

(21) Appl. No.: 14/108,369

(22) Filed: Dec. 17, 2013

(51) Int. Cl. H01L 21/02

(52) U.S. Cl. CPC H01L 21/02664; H01L 21/02529; H01L 21/02532

(57) ABSTRACT

A semiconductor process includes the steps of providing a substrate with fin structures formed thereon, performing an epitaxy process to grow an epitaxial structure on each fin structure, forming a conformal cap layer on each epitaxial structure, where adjacent conformal cap layers contact each other, and performing an etching process to separate contacting conformal cap layers.

### BACKGROUND OF THE INVENTION

1. Field of the Invention

The present invention relates to a semiconductor process, and more particularly, to a semiconductor process for manufacturing epitaxial structures.

2. Description of the Prior Art

As the semiconductor industry has progressed into nanometer technology process nodes in pursuit of higher device density, higher performance, and lower costs, challenges from both fabrication and design have resulted in the development of three dimensional designs, such as fin-like field effect transistors (FinFETs). A typical FinFET is fabricated with a thin “fin” (or fin structure) extending from a substrate, for example, etched into a silicon layer of the substrate. The channel of the FinFET is formed in the vertical fin. A gate is provided over (e.g., wrapping) the fin. It is beneficial to have a gate on both sides of the channel allowing gate control of the channel from both sides. FinFET devices also include strained source/drain features to enhance carrier mobility and improve device performance. The strained source/drain features typically use epitaxial (epi) silicon germanium (SiGe) in p-type devices and epi silicon carbide (SiC) in n-type devices, and a silicide layer formed on the strained source/drain feature for the contact to land on. FinFET devices provide numerous advantages, including reduced short channel effects and increased current flow.

Although existing FinFET devices and methods for fabricating FinFET devices have been generally adequate for their intended purposes, as device scaling down continues, they have not been entirely satisfactory in all respects. For example, in the unmerged FinFET scheme, the silicide layers on adjacent epitaxial features are usually merged and contact each other due to the small spacing between the fin structures in nano-scale semiconductor design. The contacting silicide layers on adjacent epitaxial features may lead to the bridging of adjacent individual fin structures, thereby causing device fail and low yield issues, especially in the SRAM circuit scheme.

### SUMMARY OF THE INVENTION

It is therefore the purpose of the present invention to provide a novel semiconductor process for manufacturing epitaxial structures without the conventional bridge issue. The present invention takes advantage of the property that the etching rate of Si (100) structure is inherently smaller than the etching rate of Si(111) structure to selectively trim the Si(111) tilted portion of the cap layer which contacts each other without damaging the Si(100) top portion and separate the individual epitaxial structures, thus the bridge issue is properly solved.

One object of the present invention is to provide a semiconductor process includes the steps of providing a substrate with fin structures formed thereon, performing an epitaxy process to grow an epitaxial structure on each fin structure, forming a conformal cap layers on each epitaxial structure, wherein adjacent conformal cap layers contact each other, and performing an etching process to separate contacting conformal cap layers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 schematically depicts a three dimensional diagram of fin-shaped field-effect transistor in accordance with one embodiment of the present invention.

FIGS. 2-6 are cross-sectional views schematically depicting a semiconductor process for forming epitaxial structures in accordance with one embodiment of the present invention; and

FIG. 7 is a bar chart showing the etching rate and etching rate ratio of Si(111) portion to Si(100) portion.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown byway of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

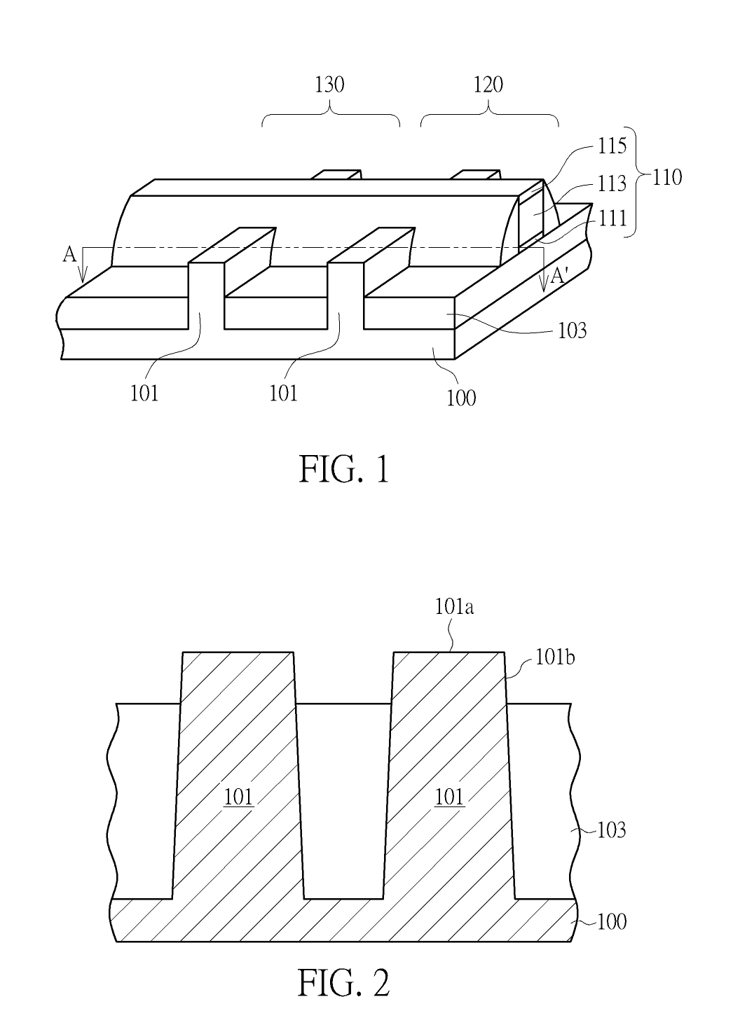

Please refer first to FIG. 1, which is a three dimensional diagram showing the standard fin-shaped field-effect transistors (FinFET) in accordance with one embodiment of the present invention. As shown in FIG. 1, first, a semiconductor substrate 100 is provided to serve as a base for forming devices, components, or circuits. The substrate 100 is preferably composed of a silicon containing material. Silicon containing materials include, but are not limited to, Si, single crystal Si, polycrystalline Si, SiGe, single crystal silicon germanium, polycrystalline silicon germanium, or silicon doped with carbon, amorphous Si and combinations and multi-layered materials thereof. The semiconductor substrate 100 may also be composed of other semiconductor materials, such as germanium, and compound semiconductor substrates, such as type III/V semiconductor substrates, e.g., GaAs. Although the semiconductor substrate 100 is depicted as a bulk semiconductor substrate, the arrangement of a semiconductor on an insulator substrate, such as silicon-on-insulator (SOI) substrates, are also suitable for the semiconductor substrate 100.

Refer again to FIG. 1, a plurality of fin structures 101 are formed on the substrate 100. The present invention takes two fin structures as an exemplary configuration to demonstrate the process flow. The fin structures 101 are spaced apart from each other by shallow trench isolations (STIs) 103. The fin structures 101 may be formed by first covering a patterned hard mask layer (ex. Si₃N₄) which defines the patterns of fin structures 101 on the substrate 100, and then an etching process is performed to etch the substrate 100 and form fin structures 101 and trenches therebetween. A dielectric material (ex. SiO₂) is filled into the trenches and then subject to a planarization process and an etch back process to form STIs 103 as shown in FIG. 1. The above-mentioned process for forming fin structures 101 and STIs 103 is well-known for those ordinarily skilled in the art, thus no detailed step-by-step descriptions and figures are shown herein to avoid obscuring the subject of the present invention.

Refer again to FIG. 1, a gate structure 110 is formed across the fin structures 101. The gate structure 110 may include gate dielectric layer 111, an electrode layer 113, and a cap layer 115. The gate structure 110 may be a tri-gate MOSFET with three contact faces to each transversed fin structures 101 thereunder, thus the width of carrier channels will be wider than a channel width of a conventional planar MOSFET. Alternatively, the gate structure 110 may be a multi-gate MOSFET with only two contact faces to each fin structure 101. In unmerged FinFET design, the gate structure 110 cooperates with each fin structure to function as a transistor device, such as FinFET 120 and 130 shown in FIG. 1.

Please refer now to FIGS. 2-6, which are cross-sectional views schematically depicting a semiconductor process for manufacturing epitaxial structures in accordance with one embodiment of the present invention. The cross-sectional views are taken with the line A-A′ in FIG. 1, which may show detailed features of the fin structure 101 and the epitaxial structures to be formed in later process.

As shown in FIG. 2, the fin structures 101 with slightly tapered profile protrude regularly from the adjacent STIs 103, so that a top surface 101a and a portion of the sidewall 101b of the fin structure 101 are exposed from the substrate 100. Those exposed surfaces will be prepared for forming the epitaxial structures. For the simplicity of the figures, gate structure 110 depicted in FIG. 1 is not shown and described in FIGS. 2-5 and following embodiment.

Refer now to FIG. 3. After the fin structures 101 and STIs 103 are formed, an epitaxy process (ex. selective epitaxial growth, SEG) is performed to form epitaxial structures 105 on the fin structure 101. In this step, the epitaxial structure 105 will be formed only on the exposed Si-based surface (i.e. the exposed top surface 101a and the sidewall 101b) of each fin structure 101. A buffer layer (not shown) may be optionally formed between the fin structures 101 and the epitaxial structures 105 to facilitate the epitaxy process. The function of epitaxial structures 105 is to increase the volume and the surface area of the fin structures 101 (that may serve as source/drain regions of transistor devices), so that the contacts or metal layers to be formed for interconnection in later processes, such as titanium (Ti), cobalt (Co), or nickel (Ni), can more easily cover or land on the surface of the epitaxial structures for performing self-aligning silicide processes. The material of the epitaxial structures 105 may include silicon germanium (SiGe), silicon carbide (SiC), a combination thereof, or other III-V compounds, depending on the type of transistor devices, such as NMOS or PMOS.

Refer again to FIG. 3. It should be noted that, in this embodiment, the epitaxial structures 105 preferably have a hexagonal shape and may include a top surface 105a and two side surfaces 105b tilted down from two sides of the top surface 105a <100>. The adjacent epitaxial structures 105 are spaced apart from each other by a spacing

D₁ between the lateral tips of side surfaces 105b <111> and are electrically isolated. The epitaxial structure 105 in the present invention is not necessarily limited in hexagonal shape, any polygons with a top surface for contact interconnection and tilted-down side surfaces which define the spacing between the transistor devices are adequately applicable.

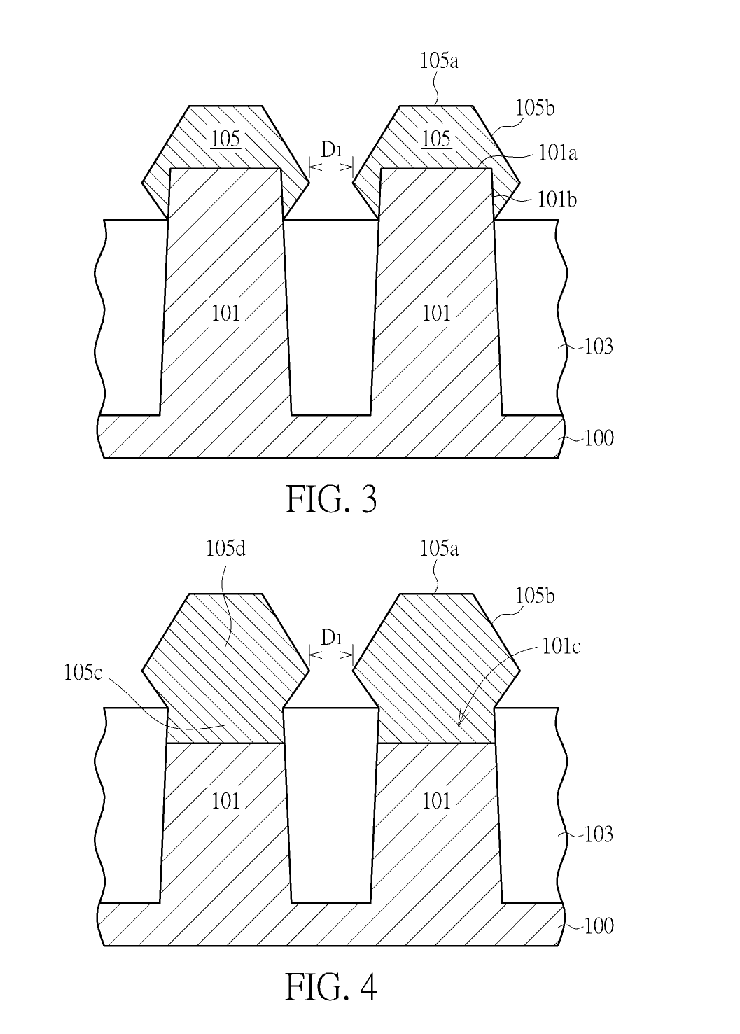

Alternatively, in other embodiment, please refer to FIG. 4. Before the epitaxy process is performed, an etching process may be first performed to etch out a portion of the protruding fin structure 101 and form a trench 101a slightly recessed below the surface of the STIs 103. The epitaxial structure 105 is then grown from the surface of the recess 101c, so that the epitaxial structure 105 will include an inner neck portion 105c and an outer hexagonal portion 105d. This design can provide not only the hexagonal portion with larger surface area for the contact to land thereon, but also provide the inner neck portion which adjoins the channel region under the gate structure 110 and is capable of providing strained stress to increase the carrier mobility.

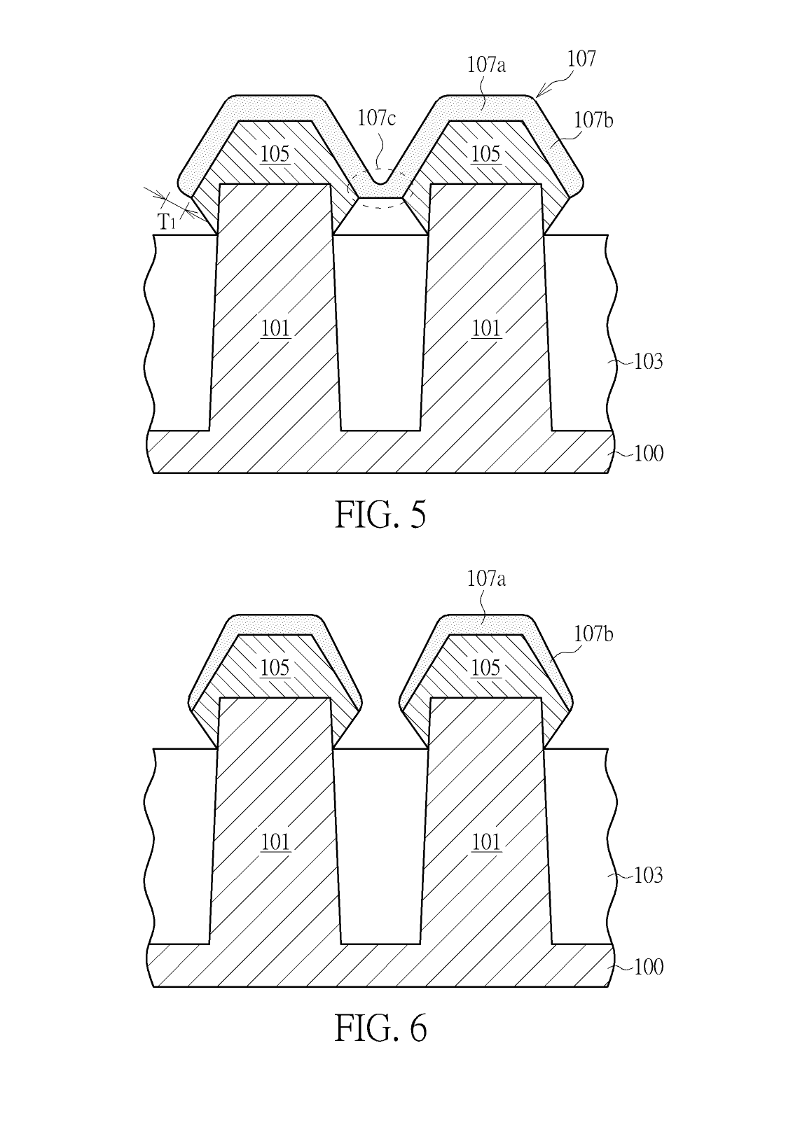

Refer now to FIG. 5. After the epitaxial structures 105 is formed, a cap layer 107 is conformally deposited on the top surface 105a and two side surfaces 105b of the epitaxial structures 105. The conformal cap layer 107 may include a top portion 107a and two side portions 107b tilted down from two sides of the top portion 107a respectively on the top surface 105a and two side surfaces 105b of the epitaxial structures 105. In this embodiment, the conformal cap layer 107 may serve as a sacrificial layer preformed on the epitaxial structures 105 to react with a metal layer and form a silicide layer. The conformal cap layer 107 is preferably made of poly Si grown on the surface of the epitaxial structures 105 by chemical vapor deposition (CVD, ex. reduced pressure CVD or atmospheric pressure CVD) with a uniform thickness T₁. This process may be in-situ process along with the epitaxy process to form the epitaxial structures. 105. In this embodiment, the thickness T₁ of the conformal cap layer 107 is larger than half of the spacing D₁ between the epitaxial structures 105, thus the cap layers 107 on adjacent epitaxial structures 105 contact each other and merge at the position of spacing D1, as the merged portion 107c shown in FIG. 3. The merged portion 107c may cause the adjacent two epitaxial structures 105 to bridge together and fail the transistor devices. This issue occurs mostly in nano-scale (ex. 20 nm or 14 nm) FinFET with unmerged SiGe approach in SRAM scheme, in which the adjacent fins or the transistor devices are very close and the marginal process window for the epitaxy is small.

Refer again to FIG. 5. Since the Si-based cap layer 107 is grown on the epitaxial structures 105 having a horizontal top surface 105a and two tilted-down side surfaces 105b, the conformal cap layer 107 will be formed correspondingly with a Si(100) top portion 107a and two tilted-down Si(111) side portions 107b respectively on the horizontal top surface 105a and two tilted-down side surfaces 105b of the epitaxial structure 105. In the embodiment, the two kinds of portions with different crystallographic orientations, i.e. the Si (100) and Si (111), is an essential feature to the present invention, since with different crystallographic orientations, one of the top portion 107a or side portions 107b may be selectively trimmed or removed by proper etching process due to the nature that the customized etching process can has different etching rates on the Si (100) surface and the Si(111) surface.

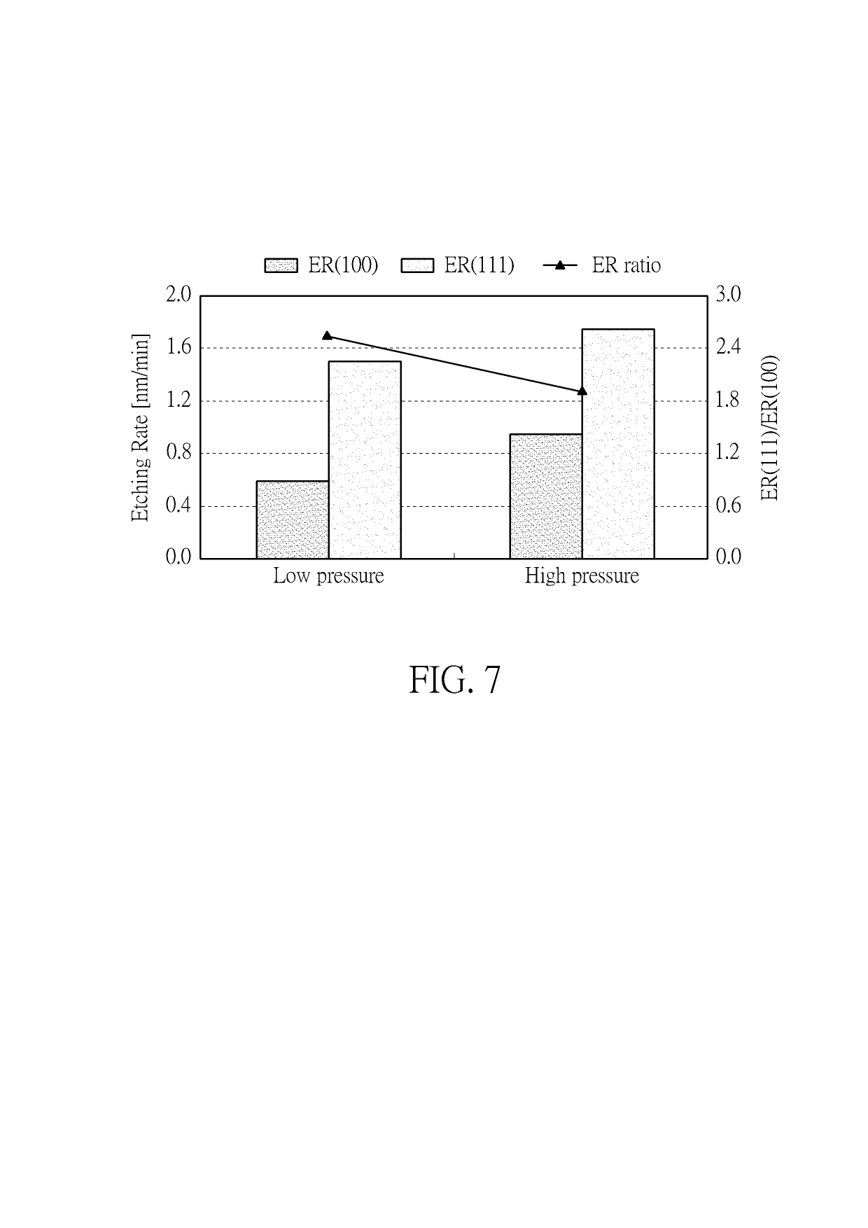

To be more specific, please refer now to FIG. 7, which is a bar chart showing the etching rates and etching rate ratios of Si (111) structure/surface to Si(100) structure/surface under low pressure and high pressure using HCl as an etchant. It is clearly shown in FIG. 5 that, whether under low pressure or high pressure, the etching rate on the Si (100) surface is far below the etching rate on the Si (111) surface in the same etching process. The etching rate ratio of Si (100) to Si(111) may reach up to about 2.4, which is an level capable of achieving a good etching selectivity to the two different portions of the cap layers 107. Preferably, the etching process is performed under low pressure about 5-20 torr to achieve adequate etching rate ratio and etching selectivity.

For this reason, please refer now to FIG. 6, which shows an etch back process E1 may be properly performed to etch the conformal cap layer 105 to remove the merged portion 107c of the cap layer 107. The etch back process E1 has a larger etching rate on the tilted-down side portions 107b than on the top portion 107a, thus the side portions 107b may be selectively trimmed or removed while the top portion remains with sufficient thickness. It can be noticed that the side portion 107b closer to the lateral tip of the side surface of the epitaxial structure 105 is subject to more etching effect and may get thinner thickness after etching due to the above-mentioned etching selectivity. The merged portion 107c of cap layer 107 is accordingly etched out and the contacting individual epitaxial structures 105 are once again separated.

In the following step, a silicide layer may be formed on the epitaxial structure 105 by using the trimmed cap layers 107 as the sacrificial layer. The silicide process may include a post clean process, a metal depositing process, an annealing process, a selective etching process, or a test process, etc. In later process, an inter-metal dielectric layer (IMD) covers on the silicide layer and the contact is formed in the IMD layer and connects the silicide layer. The silicide process is well-known in the art, thus no unnecessary detail is given herein for simplicity. Alternatively, in the post contact scheme, the silicide layer may be formed after the IMD layer is deposited and the contact hole is formed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor process for manufacturing epitaxial structures, comprising:
providing a substrate with fin structures spaced apart from each other;
performing an epitaxy process to grow an epitaxial structure on each said fin structure;
forming a conformal cap layer on each said epitaxial structure, wherein adjacent said conformal cap layers contact each other; and
performing an etching process to separate said contacting conformal cap layers.

2. The semiconductor process according to claim 1, wherein said epitaxial structure is a hexagonal structure covering on the top surface and a portion of the sidewall of said fin structure.

3. The semiconductor process according to claim 1, wherein said epitaxial structure comprises a top surface and two side surfaces tilted down from two sides of said top surface.

4. The semiconductor process according to claim 1, wherein said conformal cap layer comprises a top portion and two side portions tilted down from two sides of said top portion, and adjacent said side portions of said conformal cap layers contact each other.

5. The semiconductor process according to claim 4, wherein the etching rate of said etching process on said side portion of said conformal cap layer is larger than the etching rate of said etching process on said top portion of said conformal cap layer.

6. The semiconductor process according to claim. 4, wherein said side portions of said conformal cap layers are thinner by said etching process so that said contacting side portions of said conformal cap layers are separated.

7. The semiconductor process according to claim 4, wherein said top portion and said side portions of said conformal cap layer are a Si(100) portion and Si(111) portions respectively.

8. The semiconductor process according to claim 1, wherein said fin structures are spaced apart from each other by shallow trench isolations.

9. The semiconductor process according to claim 1, wherein the material of said epitaxial structure comprises silicon germanium (SiGe), silicon carbide (SiC), or a combination thereof.
